(19) United States
(12) Patent Application Publication
(10) Pub. No.: US 2009/0050912 A1
(43) Pub. Date: Feb. 26, 2009

(54) LIGHT EMITTING DIODE AND OUTDOOR ILLUMINATION DEVICE HAVING THE SAME

(75) Inventors: YUAN-FA CHU, Chu-Nan (TW); WEN-JANG JIANG, Chu-Nan (TW)

Correspondence Address: PCE INDUSTRY, INC.;ATT. CHENG-JU CHIANG, 458 E. LAMBERT ROAD, FULLERTON, CA, 92835, US

(73) Assignee: FOXSEMICON INTEGRATED TECHNOLOGY, INC., Chu-Nan (TW)

(21) Appl. No.: 12/192,032

(22) Filed: Aug. 14, 2008

(30) Foreign Application Priority Data
Aug. 24, 2007 (CN) 200710201465.3
Aug. 24, 2007 (CN) 200710201469.1

(51) Int. Cl. H01L 33/00

(52) U.S. Cl. 257/89; 257/E33.001

(57) ABSTRACT

A light emitting diode includes a first electrode, a second electrode, at least a first LED chip, at least a second LED chip, and an encapsulant. The second electrode has an opposite polarity with the first electrode and parallel with the first electrode. The first LED chip is electrically connected to the first electrode and the second electrode, for emitting first light of a first wavelength. The second LED chip is electrically connected to the first electrode and the second electrode, for emitting second light of a second wavelength being in a range from 570 nm to 670 nm. The encapsulant encapsulates the first and second LED chip therein, and has a phosphor material doped therein. The phosphor material is configured for emitting white light by excitation of the first light, and the second light is configured for adjusting a color temperature of the combined white light.

### CROSS-REFERENCE TO RELATED APPLICATIONS

This application claims all benefits accruing under 35 U.S.C. §119 from China Patent Application No. 200710201469.1, filed on Aug. 24, 2007 and China Patent Application No. 200710201465.3, filed on Aug. 24, 2007 in the China Intellectual Property Office, the disclosures of which are incorporated herein by reference.

### BACKGROUND

1. Technical Field

The present invention generally relates to a light emitting diode (LED), and particularly to a light source and an outdoor illumination device having the light emitting diode with adjustable color temperature.

2. Description of Related Art

In recent years, light emitting diodes (LEDs) have been widely used in consumer and commercial applications, due to their low cost, long life, high luminous efficiency, and high color rendering index (CRI). A new LED has been described in detail in a document published by Daniel A. Steigerwald et al. on March/April 2002 IEEE Journal on Selected Topics in Quantum Electronics, Vol. 8, No. 2, entitled “Illumination With Solid State Lighting Technology”, the disclosure of which is fully incorporated herein by reference.

However, a correlated color temperature (CCT) of white light emitted from a conventional LED high, being in a range from 4500K to 6500K, such white light makes the user feel cold and discomfort. At the same time, the CRI of the white light is about 80 (100 by definition), thus the CCT and CRI value cannot satisfy the user's needs. The conventional LED has a single LED chip and phosphor coated thereon to emit white light. Because of the proportional distribution for the phosphor in the LED cannot be changed after the LED has being manufactured, the color temperature of the LED cannot be adjusted during using process for the LED.

What is needed, therefore, is a light emitting diode, lighting source and outdoor illumination device with the light emitting diode capable of adjusting color temperature.

### SUMMARY

A light emitting diode includes a first electrode, a second electrode, at least a first LED chip, at least a second LED chip, and an encapsulant. The second electrode has an opposite polarity with the first electrode and parallel with the first electrode. The at least a first LED chip is electrically connected to the first electrode and the second electrode, for emitting first light of a first wavelength. The at least a second LED chip is electrically connected to the first electrode and the second electrode, for emitting second light of a second wavelength being in a range from 570 nm to 670 nm. The encapsulant encapsulates the first and second LED chip therein, and has a phosphor material doped therein. The phosphor material is configured for emitting white light by excitation of the first light, and the second light is configured for adjusting a color temperature of the combined white light.

Other advantages and novel features will become more apparent from the following detailed description of the present invention, when taken in conjunction with the accompanying drawings.

### BRIEF DESCRIPTION OF THE DRAWINGS

Many aspects of the present light emitting diode, lighting source, and outdoor illumination device can be better understood with reference to the following drawings. The components in the drawings are not necessarily drawn to scale, the emphasis instead being placed upon clearly illustrating the principles of the present light emitting diode, lighting source, and outdoor illumination device.

FIG. 1 is a schematic, cross-sectional view of a light emitting diode, in accordance with a first embodiment.

FIG. 2 is schematic, cross-sectional view of a light emitting diode, in accordance with a second embodiment.

FIG. 3 is a schematic, cross-sectional view of a light emitting diode, in accordance with a third embodiment.

FIG. 4 a schematic, isometric view of a lighting source, in accordance with a fourth embodiment.

FIG. 5 a schematic, isometric view of a lighting source, in accordance with a fifth embodiment.

FIG. 6 a schematic, isometric view of an outdoor illumination device, in accordance with a sixth embodiment.

Corresponding reference characters indicate corresponding parts throughout the drawings. The exemplifications set out herein illustrate at least one embodiment of the present invention, in one form, and such exemplifications are not to be construed as limiting the scope of the invention in any manner.

### DETAILED DESCRIPTION OF THE EMBODIMENTS

Reference will now be made to the drawings to describe the embodiments of the present light emitting diode, lighting source, and outdoor illumination device.

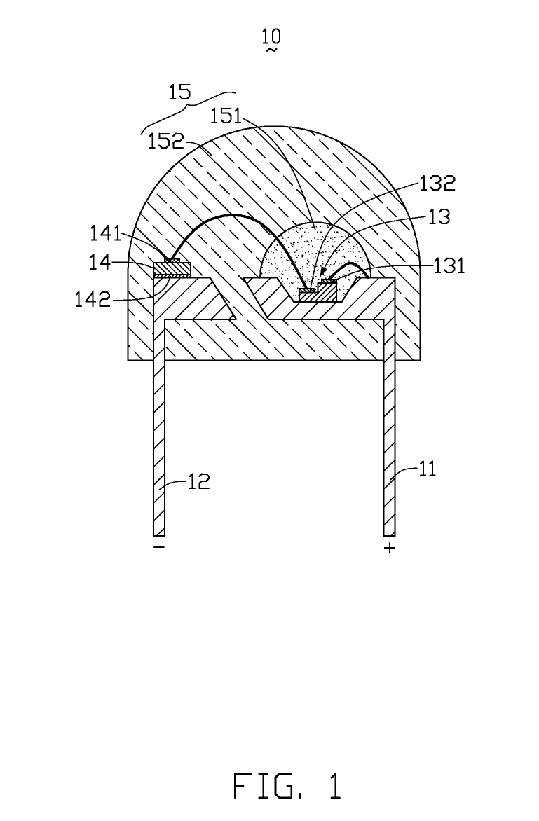

Referring to FIG. 1, a light emitting diode 10, in accordance with a first embodiment, is provided. The light emitting diode 10 includes a first electrode 11, a second electrode 12, a first LED chip 13, a second LED chip 14, and an encapsulant 15.

The first electrode 11 and the second electrode 12 are combined to form a lead frame. The second electrode 12 has an opposite polarity with respect to the first electrode 11. In the exemplary embodiment, the first electrode 11 is a positive electrode and the second electrode 12 is a negative electrode.

The first LED chip 13 is electrically connected with the second LED chip 14 in series. The first LED chip 13 and second LED chip 14 are electrically connected to the first electrode 11 and second electrode 12. The first LED chip 13 is configured for emitting a first light of a first wavelength. The first LED chip 13 includes a first electrical contact 131 and a second electrical contact 132 which are located at the same side thereof. The first LED chip 13 is mounted on the first electrode 11, and the first electrical contact 131 and a second electrical contact 132 which are away from the first electrode 11. The first electrical contact 131 of the first LED chip 13 is connected to the first electrode 11 via wire bonding.

The second LED chip 14 is configured for emitting second light of a second wavelength which is in a range from 570 nm to 670 nm. The second LED chip 14 includes a first electrical contact 141 and a second electrical contact 142 opposite to the first electrical contact 141. The polarity of the first electrical contact 141 is same as it of the first electrical contact 131. The second LED chip 14 is mounted on the second electrode 12. The first electrical contact 141 of the second LED chip 14 is connected to the second electrical contact 132 of the first LED chip 13 via wire bonding. The second electrical contact 142 of the second LED chip 14 is electrically connected with the second electrode 12 directly.

The first LED chip 13 and second LED chip 14 can be made of the III-V compound. For example, the first LED chip 13 is made of Aluminum Indium Gallium Nitride (AlInGaN), and the second LED chip 14 is made of Aluminum Indium Gallium Phosphide (AlInGaP).

It can be understood that the number of the first LED chip 13 and the second LED chip in the light emitting diode 10 may be one or more.

The encapsulant 15 includes an inner part 151 and an outer part 152. The inner part 151 is placed on the first electrode 11 to cover the first LED chip 13, and the outer part 152 is placed on the first electrode 11 and the second electrode 12 to cover the second LED chip 14 and a periphery of the inner part 151. The inner part 151 has phosphor material doped therein. The phosphor material is excited by the first light from the first LED chip 13 and emits white light out of the encapsulant 15. The phosphor material is selected from the group consisting of yttrium aluminum garnet (YAG), terbium aluminum garnet (TAG), silicate phosphor and nitride phosphor.

The first electrode 11 and second electrode 12 are connected to a driving control unit (not shown). The first LED chip 13, second LED chip 14 and the driving control unit cooperatively form an electrical loop. The driving control unit is configured for controlling a current passed through the electrical loop to adjust the brightness of light emitted from the first LED chip 13 and second LED chip 14. The first light emitted from the first LED chip 13 excites the phosphor material to emit white light out of the encapsulant 15, and the second light with the second wavelength emitted from the second LED chip 14 emit directly out of the encapsulant 15. The brightness of the second light with the second wavelength can be adjusted via controlling the current passed through the electrical loop by the driving control unit, such that the color temperature of the white light emitted from the light emitting diode 10 can be adjusted.

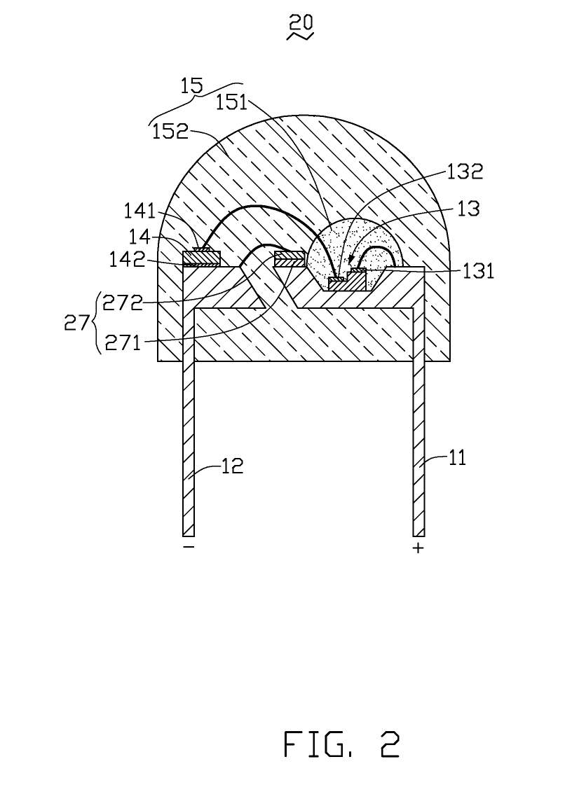

Referring to FIG. 2, a light emitting diode 20, in accordance with a second embodiment, is provided. The light emitting diode 20 of the exemplary second embodiment is similar to that of the first embodiment, except that and the present light emitting diode 20 further include a diode chip 27. The diode chip 27 is connected to the first LED chip 13 and second LED chip 14 in inverse parallel. In this exemplary embodiment, the first electrode 11 is a positive electrode and the second electrode 12 is a negative electrode. A negative electrode 271 and a positive electrode 272 of the diode chip 27 are electrically connected to the first electrode 11 and second electrode 12 respectively. The diode chip 27 is configured for preventing the first LED chip 13 from being damaged under a large inversed voltage. When the first electrode 11 and second electrode 12 are connected to a driving control unit (not shown), the first LED chip 13 and second LED chip 14 are connected to the driving control unit in series. Brightness of the second light with the second wavelength can be adjusted via controlling the current passing through the electrical loop by the driving control unit, such that the color temperature of the white light emitted from the light emitting diode 20 can be adjusted.

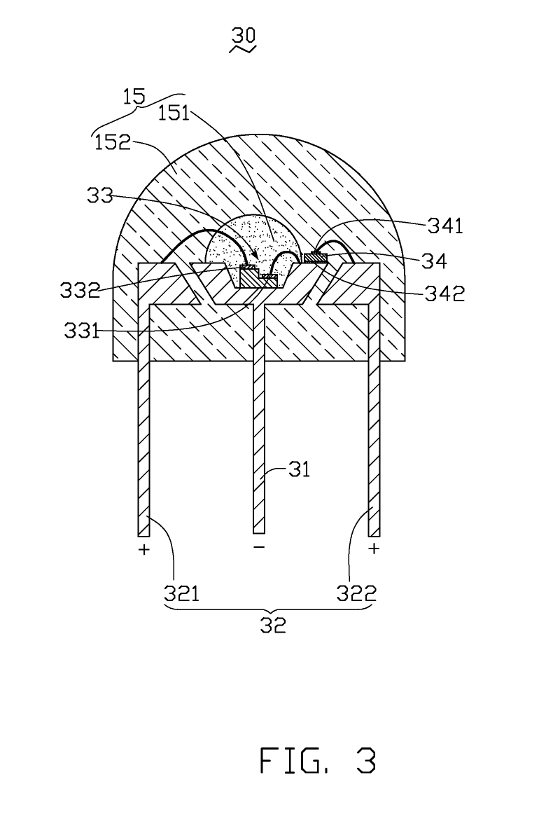

Referring to FIG. 3, a light emitting diode 30, in accordance with a third embodiment, is provided. The light emitting diode 30 includes a first electrode 31, a second electrode 32, a first LED chip 33, a second LED chip 34, and an encapsulant 15.

The second electrode 32 includes a first section 321 and a second section 322. The polarity of the first section 321 is same as it of the second section 322. The first section 321 and the second section 322 are respectively placed on two opposite sides of the first electrode 31. In the exemplary embodiment, the first electrode 31 is a negative electrode and the first section 321 and a second section 322 of the second electrode 32 both are positive electrode.

The first LED chip 33 is electrically connected to the first electrode 31 and the first section 321 of the second electrode 32. In the exemplary embodiment, the first LED chip 33 is configured for emitting light with the first wavelength. The first LED chip 33 includes a first electrical contact 331 and a second electrical contact 332 which are located at the same side thereof. The first LED chip 33 is mounted on the first electrode 31 and the first electrical contact 331 and a second electrical contact 332 which are away from the first electrode 31. The first electrical contact 331 of the first LED chip 33 is connected to the first electrode 31 via wire bonding, and the second electrical contact 332 is connected to the first section 321 of the second electrode 32 via wire bonding.

The second LED chip 34 is electrically connected to the first electrode 31 and the second section 322 of second electrode 32. The second LED chip 34 is configured for emitting second light of a second wavelength which is in a range from 570 nm to 670 nm. In the exemplary embodiment, the second LED chip 34 is mounted on the first electrode 31 and adjacent to the first LED chip 33. The second LED chip 34 includes a first electrical contact 341 and a second electrical contact 342 opposite to the first electrical contact 341. The polarity of the first electrical contact 341 is same as it of the second section 322 of second electrode 32. The first electrical contact 341 of the second LED chip 34 is connected to the second section 322 of second electrode 32 via wire bonding. The second electrical contact 342 of the second LED chip 34 is connected to the first electrode 31 directly.

The phosphor material doped in inner part 151 of the encapsulant 15 can be excited by the first light from the first LED chip 33 and emits white light out of the encapsulant 15 through the outer part 152 thereof.

The first electrode 31 and the first section 321 of second electrode 32 are configured for being connected to a first driving control unit (not shown), and simultaneously the first electrode 31 and the second section 322 of second electrode 32 are configured for being connected to a second driving control unit (not shown). The first LED chip 33 is located in a first electrical loop that controlled by the first driving control unit, and the second LED chip 34 is located in a second electrical loop that controlled by the second driving control unit. The brightness of the light emitted from the first LED chip 33 can be adjusted via controlling current passed through the first LED chip 33 by the first driving control unit, and simultaneously the brightness of the light emitted from the second LED chip 34 can be adjusted via controlling current passed through the second LED chip 34 by the second driving control unit. The first light emitted from the first LED chip 33 excites the phosphor material to emit white light out of the encapsulant 15, and the second light with the second wavelength emitted from the second LED chip 34 emit directly out of the encapsulant 15. The brightness of the light with the second wavelength can be adjusted via controlling the current passed through the second electrical loop by the second driving control unit, such that the color temperature of the white light emitted from the light emitting diode 30 can be adjusted.

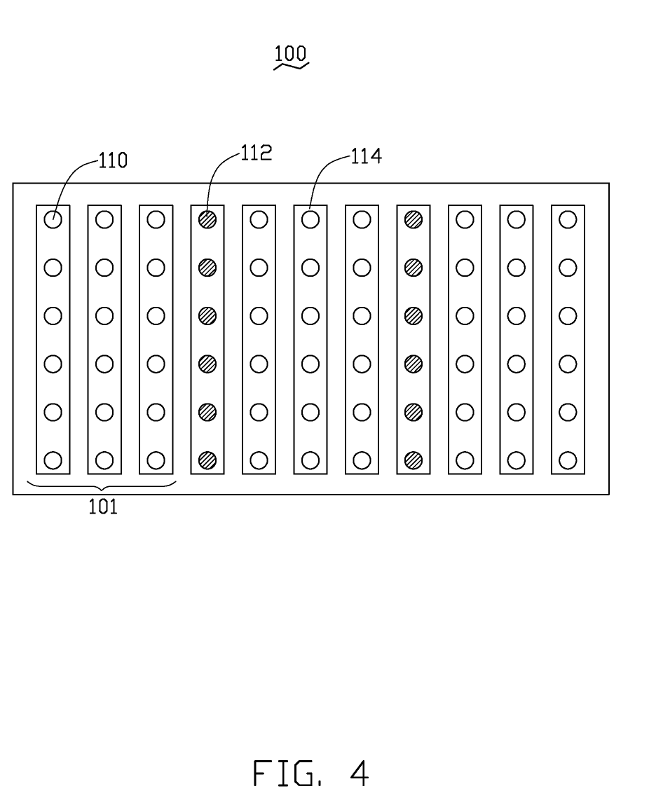

Referring to FIG. 4, a lighting source 100, in accordance with a fourth embodiment, is provided. The lighting source 100 includes a number of white LEDs 110 with adjustable brightness and a plurality of warm LEDs 112 with adjustable brightness. The white LEDs 110 and warm LEDs 112 are arranged in an array. The warm LEDs 112 are evenly located between the white LEDs 110. The white LEDs 110 are configured for emitting white light. The warm LEDs 112 are configured for emitting light having a wavelength being in a range from 570 nm to 670 nm, and they may be orange LEDs, yellow LEDs, red LEDs, amber LEDs or a combination thereof. In the exemplary embodiment, the white LEDs 110 and warm LEDs 112 are connected to a driving control unit (not shown), and the driving control unit is configuring for controlling brightness of the white LEDs 110 and the warm LEDs 112 respectively. Therefore, the color temperature of white light from the white LEDs 110 can be adjusted by changing brightness of the warm LEDs 112.

Each of the white LEDs 110 includes a first LED chip and phosphor material therein. The first LED chip can emit a first light with a first wavelength. The phosphor material in the white LEDs 110 is excited by the first light to emit white light. The first LED chip can be made of the III-V compound, such as Aluminum Indium Gallium Nitride (AlInGaN).

The warm LEDs 112 includes a second LED chip therein. The second LED chip can emit a second light of a second wavelength. The second wavelength is in a range from 570 nm to 670 nm. The second LED chip can be made of the III-V compound, such as Aluminum Indium Gallium Phosphide (AlInGaP).

The lighting source 100 includes several white LED groups 101 each consisting of a number of white LEDs 110. Two or more warm LEDs 112 are arranged between adjacent white LED groups 101, that is the warm LEDs 112 can be evenly spaced apart from the white LED groups 101.

The lighting source 100 further includes a number of reflective plates 114. The reflective plates 114 are patterned to have a strip shape, and arranged parallel with each other. Each of the reflective plates 114 faces toward respective white LEDs 110, warm LEDs 112, or a combination thereof. The reflective plate 114 is used to reflect the light from the white LEDs 110, the warm LEDs 112, or a combination thereof, to improve utilization ratio of light from the lighting source 100. FIG. 4 shows the white LED groups 101 is located opposite to three adjacent reflective plates 114, a reflective plate 114 is placed between two adjacent white LED groups 101 and opposite to a number of warm LEDs 112.

It can be understood that, the lighting source 100 may only includes one reflective plate 114. This reflective plate 114 is located opposite to all the white LEDs 110 and warm LEDs 112. The shape and position of the reflective plate 114 can be designed based on the factual needs, so as to improve light utilization ratio of the lighting source 100. In the exemplary embodiment, the reflective plate 114 has a round shape. In addition, the white LEDs 110 and warm LEDs 112 may be mixed together in an array, in favor of adjusting color temperature and color rendering index.

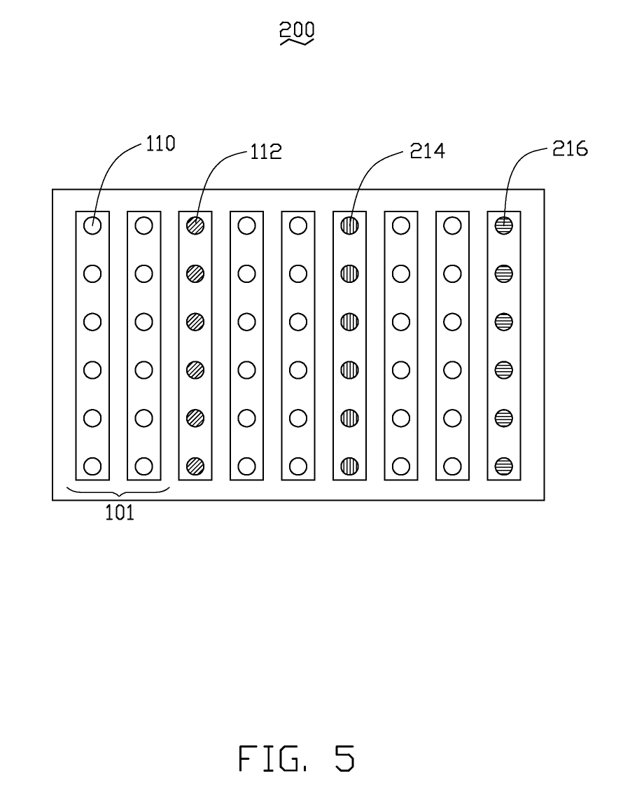

Referring to FIG. 5, a lighting source 200, in accordance with a fifth embodiment, is provided. The lighting source 200 of exemplary fifth embodiment is similar to that of the fourth embodiment, and the lighting source 200 further includes a number of green LEDs 214 and blue LEDs 216 besides the white LEDs 110 and warm LEDs 112. The warm LEDs 112, green LEDs 214, and blue LEDs 216 are evenly located between the white LEDs 110 or between two adjacent white LED groups 101. The green LEDs 214 and blue LEDs 216 are configured for electrically connecting to the driving control unit simultaneously. Brightness of light from the warm LEDs 112, green LEDs 214, and blue LEDs 216 can be adjusted respectively.

Because of the lighting source 200 also includes the green LEDs 214 and the blue LEDs 216, color temperature of the white light emitted from the lighting source 200 can be adjusted by respectively adjusting brightness of the warm LEDs 112, green LEDs 214, and blue LEDs 216, thereby the lighting source 200 has CRI up to about 85 (100 by definition) and can emit the light with more colors. Colors of the light from the lighting source 200 in accordance with the exemplary embodiment can be micro-adjusted, so that the lighting source 200 is adapted to be used in the mood lighting.

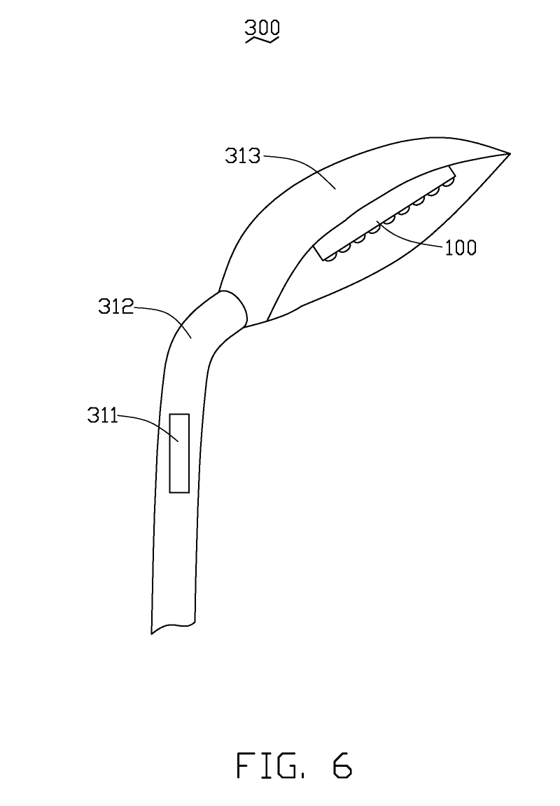

Referring to FIG. 6, an outdoor illumination device 300, in accordance with a sixth embodiment, is provided. The outdoor illumination device 300 includes the lighting source 100 described above, a driving control unit 311, a lamp pole 312, and a lamp housing 313 installed on the lamp pole 312. The lighting source 100 is received in the lamp housing 313. The driving control unit 311 is installed on the lamp pole 312 and electrically connected to the lighting source 100. It can be understood that, the driving control unit 311 may be installed on the lamp housing 313. Brightness of light from the white LEDs 110 and warm LEDs 112 can be adjusted via controlling the current passed through the white LEDs 110 and warm LEDs 112 by the driving control unit 311, such that color temperature of the white light emitted from the lighting source 100 can be adjusted. Therefore, “warm light” can be emitted from the lighting source 100, which would let the user feel comfortably. In the exemplary embodiment, white light emitted from the lighting source 100 may have color temperature down to 2500K via adjusting the brightness of light from the warm LEDs 112 by the driving control unit 311.

The outdoor illumination device 300 may includes the lighting source 200 provided in the fifth embodiment, brightness of light from the warm LEDs 112, green LEDs 214 and blue LEDs 216 can be adjusted respectively via controlling the current passed through the warm LEDs 112, green LEDs 214 and blue LEDs 216 by the driving control unit 311, such that color temperature of the white light emitted from the white LEDs 110 can be adjusted.

It is to be understood that the above-described embodiment is intended to illustrate rather than limit the invention. Variations may be made to the embodiment without departing from the spirit of the invention as claimed. The above-described embodiments are intended to illustrate the scope of the invention and not restrict the scope of the invention.

What is claimed is:

1. A light emitting diode comprising:
a first electrode;
a second electrode, which having an opposite polarity with respect to the first electrode and being in parallel with the first electrode;
at least a first LED chip electrically connected to the first electrode and the second electrode, for emitting first light of a first wavelength;
at least a second LED chip electrically connected to the first electrode and the second electrode, for emitting second light of a second wavelength being in a range from 570 nm to 670 nm;
an encapsulant encapsulating the first LED chip and the second LED chip therein and having a phosphor material doped therein, the phosphor material configured for emitting white light by excitation of the first light, the second light configured for adjusting a color temperature of the combined white light.

2. The light emitting diode of claim 1, wherein the at least a first LED chip is electrically connected with the at least a second LED chip in series.

3. The light emitting diode of claim 1, further comprising a diode chip, the diode chip is connected to the at least a first LED chip in inverse parallel.

4. The light emitting diode of claim 1, wherein the at least a first LED chip and the at least a second LED chip are mounted on the first electrode and adjacent to each other, the second electrode comprises a first section and a second section, the at least a first LED chip is electrically connected to the first section and the first electrode, the at least a second LED chip is electrically connected with the second section and the first electrode.

5. The light emitting diode of claim 1, wherein the at least a first LED chip is made of AlInGaN, the at least a second LED chip is made of AlInGaP.

6. The light emitting diode of claim 1, wherein the encapsulant comprises an inner part and an outer part, the inner part is configured for covering the at least a first LED chip, the outer part is configured for covering the at least a second LED chip and a periphery of the inner part, the phosphor material is doped in the inner part.

7. The light emitting diode of claim 1, wherein the phosphor material is selected from the group consisting of yttrium aluminum garnet, terbium aluminum garnet, silicate phosphor and nitride phosphor.

8. A lighting source, comprising:
a plurality of white LEDs for emitting white light with adjustable brightness, the white LEDs arranged in an array;
a plurality of warm LEDs for emitting second light with adjustable brightness, the warm LEDs arranged in an array adjacent to the white LEDs, the second light having a wavelength being in a range from 570 nm to 670 nm.

9. The lighting source of claim 8, wherein each white LED comprises a phosphor material and a first LED chip therein, the first LED chip is configuring for emitting first light with a first wavelength to excite the phosphor material to emit white light.

10. The lighting source of claim 8, wherein the warm LED comprises a second LED chip therein, the second LED chip is configured for emitting the second light.

11. An outdoor illumination device, comprising:
a lighting source; and
a driving control unit, the lighting source comprising a plurality of white LEDs arranged in an array and a plurality of warm LEDs adjacent to the white LEDs and arranged in an array, the warm LEDs being configured for emitting light having a wavelength being in a range from 570 nm to 670 nm, the driving control unit electrically connected to the white LEDs and warm LEDs and configured for adjusting the brightness of the light from the white LEDs and warm LEDs.

12. The outdoor illumination device of claim 1, further comprising a lamp pole and a lamp housing installed thereon, wherein the lighting source is received in the lamp housing.

13. The outdoor illumination device of claim 1, wherein the warm LEDs are orange LEDs, yellow LEDs, red LEDs, amber LEDs or a combination thereof.

14. The outdoor illumination device of claim 1, wherein the plurality of white LEDs comprises a plurality of white LED groups each consisting of two or more white LEDs, and at least one warm LED is arranged between adjacent white LED groups.

15. The outdoor illumination device of claim 11, further comprising a reflective plate opposite to all the white LEDs and warm LEDs, wherein the reflective plate is configured for reflecting the light from all the white LEDs and warm LEDs.

16. The outdoor illumination device of claim 11, further comprising a plurality of reflective plates arranged parallel with each other, wherein each of the reflective plates faces toward respective white LEDs, warm LEDs, or a combination thereof.

17. The outdoor illumination device of claim 11, wherein the lighting source further comprises a plurality of green LEDs and blue LEDs that arranged in an array, the warm LEDs, green LEDs, and blue LEDs are evenly located between the white LEDs, the driving control unit is electrically connected to the green LEDs and blue LEDs to respectively adjust brightness of the green LEDs and blue LEDs.
